(19) United States
(12) Patent Application Publication
(10) Pub. No.: US 2021/0065073 A1
(43) Pub. Date: Mar. 4, 2021

(54) SYSTEM AND METHOD FOR PRESENTING ELECTRIC VEHICLE CHARGING OPTIONS

(71) Applicant: Honda Motor Co., Ltd., Tokyo (JP)

(72) Inventors: Eri Izumi Maeda, Rancho Palos Verdes, CA (US); David Wong Cun, Fountain Valley, CA (US)

(21) Appl. No.: 17/095,013

(22) Filed: Nov. 11, 2020

Related U.S. Application Data
(63) Continuation-in-part of application No. 16/593,580, filed on Oct. 4, 2019.
(60) Provisional application No. 62/886,895, filed on Aug. 14, 2019.

(51) Int. Cl. G06Q 10/02; G06Q 30/02; G06Q 50/06; H04L 29/08; G01R 31/382; G01S 19/01

(52) U.S. Cl. CPC G06Q 10/02; G06Q 30/0283; G01S 19/01; H04L 67/18; G01R 31/382; G06Q 50/06

(57) ABSTRACT

A system and method for presenting electric vehicle charging options. The system and method also include determining at least one charging station that is within a remaining distance that the electric vehicle is capable of traveling based on the current geo-location of the electric vehicle and the current state of charge of the battery of the electric vehicle. The system and method further include presenting a charging station map user interface that pin points the current geo-location of the electric vehicle and the at least one charging station. One or more of the charging stations are presented with labels. The system and method further include reserving the at least one charging station for charging the electric vehicle by selecting one or more particular user interface selectable geo-locations that are presented on the charging station map user interface.

### CROSS-REFERENCE TO RELATED APPLICATION

This application claims priority to U.S. Provisional Application Ser. No. 62/886,895 filed on Aug. 14, 2019 and U.S. Non-Provisional application Ser. No. 16/593,580 filed on Oct. 4, 2019, which are expressly incorporated herein by reference.

### BACKGROUND

Electric vehicles contain electric storage mechanisms (e.g., electric engines powered by rechargeable batteries) to store electricity and power the electric vehicles. The electric storage mechanisms may be replenished periodically by using, for example, charging equipment installed at a residential home or charging equipment installed at public or private charging stations. Operators of electric vehicles may be typically concerned about balancing charging efficiency and costs. In many cases, when operators connect their electric vehicles to charge, the electric vehicles may charge to a maximum state of charge at one or more charging speeds (e.g., 100% state of charge of the rechargeable batteries) regardless of the cost of energy during the charging session.

In many cases, operators may not be aware of additional or alternate locations at which charging may be completed at cheaper rates. In other cases, operators may arrive at a station and may not be able to charge their electric vehicle based on a backlog of additional customers that are charging their respective electric vehicles or are waiting in a queue to charge their respective electric vehicles. Additionally, operators may not be able to take advantage of cost savings with respect to charging stations, charge times, and/or additional charging resources that may be available to them and that may be utilized to balance electric vehicle charging efficiency and costs.

### BRIEF DESCRIPTION

According to one aspect, a computer-implemented method for presenting electric vehicle charging options that includes determining a current geo-location of an electric vehicle and determining a current state of charge of a battery of the electric vehicle. The computer-implemented method also includes identifying a plurality of charging stations that are within a remaining distance that the electric vehicle is capable of traveling based on the current geo-location of the electric vehicle and the current state of charge of the battery of the electric vehicle. The computer-implemented method further includes presenting a charging station map user interface that pin points the current geo-location of the electric vehicle and each of the charging stations of the plurality of charging stations. One or more of the charging stations are presented with labels. The computer-implemented method also includes reserving a charging station of the plurality of charging stations by selecting a particular user interface selectable geo-location that is presented on the charging station map user interface.

According to another aspect, a system for presenting electric vehicle charging options that includes a memory storing instructions when executed by a processor cause the processor to determine a current geo-location of an electric vehicle and determine a current state of charge of a battery of the electric vehicle. The instructions also cause the processor to determine a plurality of charging stations that are within a remaining distance that the electric vehicle is capable of traveling based on the current geo-location of the electric vehicle and the current state of charge of the battery of the electric vehicle. The instructions further cause the processor to present a charging station map user interface that pin points the current geo-location of the electric vehicle and the at least one charging station. One or more of the charging stations are presented with labels. The instructions also cause the processor to reserve a charging station of the plurality of charging stations by selecting a particular user interface selectable geo-location that is presented on the charging station map user interface.

According to still another aspect, a non-transitory computer readable storage medium storing instructions that when executed by a computer, which includes a processor perform a method, the method includes determining a current geo-location of an electric vehicle and determining a current state of charge of a battery of the electric vehicle. The method also includes determining that a plurality of charging stations are within a remaining distance that the electric vehicle is capable of traveling based on the current geo-location of the electric vehicle and the current state of charge of the battery of the electric vehicle. The method further includes presenting a charging station map user interface that pin points the current geo-location of the electric vehicle and each charging station of the plurality of charging stations. One or more of the charging stations are presented with labels. The method also includes reserving a charging station of the plurality of charging stations by selecting a particular user interface selectable geo-location that is presented on the charging station map user interface.

### BRIEF DESCRIPTION OF THE DRAWINGS

The novel features believed to be characteristic of the disclosure are set forth in the appended claims. In the descriptions that follow, like parts are marked throughout the specification and drawings with the same numerals, respectively. The drawing figures are not necessarily drawn to scale and certain figures can be shown in exaggerated or generalized form in the interest of clarity and conciseness. The disclosure itself, however, as well as a preferred mode of use, further objects and advances thereof, will be best understood by reference to the following detailed description of illustrative embodiments when read in conjunction with the accompanying drawings, wherein:

FIG. 1 is a high-level schematic view of an illustrative system for providing enhanced electric vehicle charging according to an exemplary embodiment of the present disclosure.

FIG. 2 is a schematic view of an illustrative electric vehicle architecture according to an exemplary embodiment of the present disclosure.

FIG. 3 is a schematic view of an illustrative remote server architecture according to an exemplary embodiment of the present disclosure.

FIG. 4 is a schematic view of a plurality of modules of a smart charge application that may execute computer-implemented instructions for presenting electric vehicle charging options according to an exemplary embodiment of the present disclosure.

FIG. 5 is an illustrative example of a charging station map user interface according to an exemplary embodiment of the present disclosure.

FIG. 6 is a process flow diagram of a method for presenting the charging station map user interface with one or more charging stations based on the current geo-location of an electric vehicle (EV) and the state of charge (SOC) of a battery of the EV according to an exemplary embodiment of the present disclosure.

FIG. 7 is a process flow diagram of a method for presenting the charging station map user interface with one or more charging stations that are located near one or more perspective travel paths that may be utilized by the EV 102 according to an exemplary embodiment of the present disclosure.

FIG. 8 is a process flow diagram of a method for presenting electric vehicle charging options according to an exemplary embodiment of the present disclosure.

FIG. 9 is an illustrative example of a charging station map user interface for use with a user interface according to an exemplary embodiment of the present disclosure.

### DETAILED DESCRIPTION

The following includes definitions of selected terms employed herein. The definitions include various examples and/or forms of components that fall within the scope of a term and that may be used for implementation. The examples are not intended to be limiting.

A “bus”, as used herein, refers to an interconnected architecture that is operably connected to other computer components inside a computer or between computers. The bus may transfer data between the computer components. The bus may be a memory bus, a memory controller, a peripheral bus, an external bus, a crossbar switch, and/or a local bus, among others. The bus may also be a vehicle bus that interconnects components inside a vehicle using protocols such as Controller Area network (CAN), Local Interconnect Network (LIN), among others.

“Computer communication”, as used herein, refers to a communication between two or more computing devices (e.g., computer, personal digital assistant, cellular telephone, network device) and may be, for example, a network transfer, a file transfer, an applet transfer, an email, a hypertext transfer protocol (HTTP) transfer, and so on. A computer communication may occur across, for example, a wireless system (e.g., IEEE 802.11), an Ethernet system (e.g., IEEE 802.3), a token ring system (e.g., IEEE 802.5), a local area network (LAN), a wide area network (WAN), a point-to-point system, a circuit switching system, a packet switching system, among others.

A “computer-readable medium”, as used herein, refers to a medium that provides signals, instructions and/or data. A computer-readable medium may take forms, including, but not limited to, non-volatile media and volatile media. Non-volatile media may include, for example, optical or magnetic disks, and so on. Volatile media may include, for example, semiconductor memories, dynamic memory, and so on. Common forms of a computer-readable medium include, but are not limited to, a floppy disk, a flexible disk, a hard disk, a magnetic tape, other magnetic medium, other optical medium, a RAM (random access memory), a ROM (read only memory), and other media from which a computer, a processor or other electronic device may read.

A “data store”, as used herein can be, for example, a magnetic disk drive, a solid state disk drive, a floppy disk drive, a tape drive, a Zip drive, a flash memory card, and/or a memory stick. Furthermore, the disk can be a CD-ROM (compact disk ROM), a CD recordable drive (CD-R drive), a CD rewritable drive (CD-RW drive), and/or a digital video ROM drive (DVD ROM). The disk can store an operating system that controls or allocates resources of a computing device. The data store can also refer to a database, for example, a table, a set of tables, a set of data stores (e.g., a disk, a memory, a table, a file, a list, a queue, a heap, a register) and methods for accessing and/or manipulating those data in those tables and data stores. The data store can reside in one logical and/or physical entity and/or may be distributed between two or more logical and/or physical entities.

A “memory”, as used herein can include volatile memory and/or non-volatile memory. Non-volatile memory can include, for example, ROM (read only memory), PROM (programmable read only memory), EPROM (erasable PROM), and EEPROM (electrically erasable PROM). Volatile memory can include, for example, RAM (random access memory), synchronous RAM (SRAM), dynamic RAM (DRAM), synchronous DRAM (SDRAM), double data rate SDRAM (DDR SDRAM), and direct RAM bus RAM (DRRAM). The memory can store an operating system that controls or allocates resources of a computing device.

An “operable connection”, or a connection by which entities are “operably connected”, is one in which signals, physical communications, and/or logical communications can be sent and/or received. An operable connection can include a physical interface, a data interface and/or an electrical interface.

A “processor”, as used herein, processes signals and performs general computing and arithmetic functions. Signals processed by the processor can include digital signals, data signals, computer instructions, processor instructions, messages, a bit, a bit stream, or other means that may be received, transmitted and/or detected. Generally, the processor may be a variety of various processors including multiple single and multicore processors and co-processors and other multiple single and multicore processor and co-processor architectures. The processor may include various modules to execute various functions.

A “portable device”, as used herein, is a computing device typically having a display screen with user input (e.g., touch, keyboard) and a processor for computing. Portable devices include, but are not limited to, key fobs, handheld devices, mobile devices, smart phones, laptops, tablets and e-readers.

An “electric vehicle” (EV), as used herein, refers to any moving vehicle that is capable of carrying one or more human occupants and is powered entirely or partially by one or more electric motors powered by an electric battery. The EV may include battery electric vehicles (BEVs), plug-in hybrid electric vehicles (PHEVs) and extended range electric vehicles (EREVs). The term “vehicle” includes, but is not limited to: cars, trucks, vans, minivans, SUVs, motorcycles, scooters, boats, personal watercraft, and aircraft.

A “value” and “level”, as used herein may include, but is not limited to, a numerical or other kind of value or level such as a percentage, a non-numerical value, a discrete state, a discrete value, a continuous value, among others. The term “value of X” or “level of X” as used throughout this detailed description and in the claims refers to any numerical or other kind of value for distinguishing between two or more states of X. For example, in some cases, the value or level of X may be given as a percentage between 0% and 100%. In other cases, the value or level of X could be a value in the range between 1 and 10. In still other cases, the value or level of X may not be a numerical value, but could be associated with a given discrete state, such as “not X”, “slightly x”, “x”, “very x” and “extremely x”.

### I. System Overview:

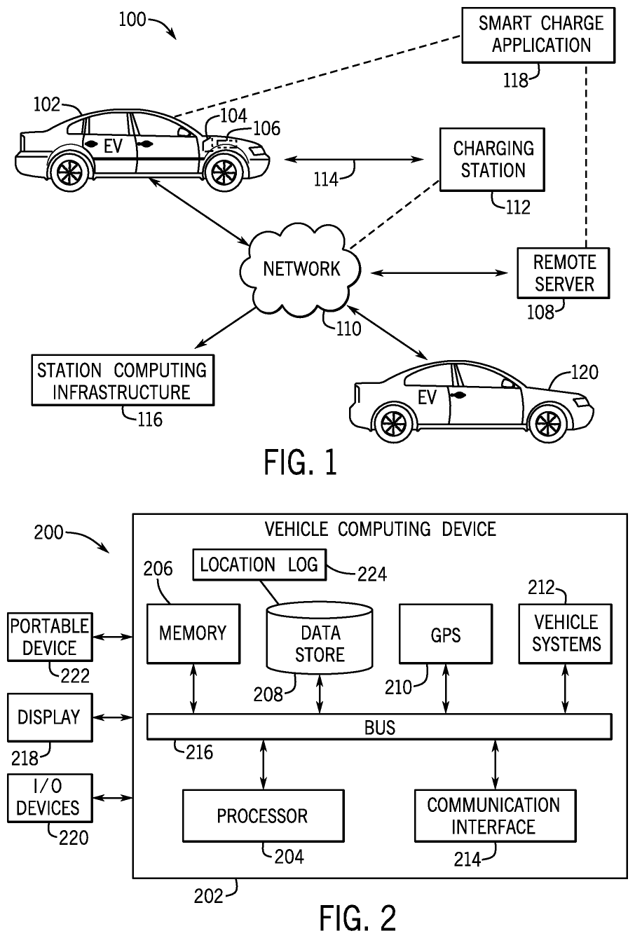

Referring now to the drawings, wherein the showings are for purposes of illustrating one or more exemplary embodiments and not for purposes of limiting same, FIG. 1 is a high-level schematic view of an illustrative system 100 for presenting electric vehicle charging options according to an exemplary embodiment of the present disclosure. The components of the system 100, as well as the components of other systems and architectures discussed herein, may be combined, omitted or organized into different architectures for various embodiments.

In the exemplary embodiment of FIG. 1, the system 100 includes an electric vehicle (EV) 102 powered by an electric motor 104 and an electric storage mechanism, for example, a battery 106. In one embodiment, the EV 102 is purely electric in that it only has the electric motor 104. In other embodiments, the EV 102 may have the electric motor 104 and an internal combustion engine (not shown). In some embodiments, the EV 102 may have any number of electric motors, batteries, and/or internal combustion engines and they may operate in series (e.g., as in an extended range electric vehicle), in parallel, or some combination of series and parallel operation.

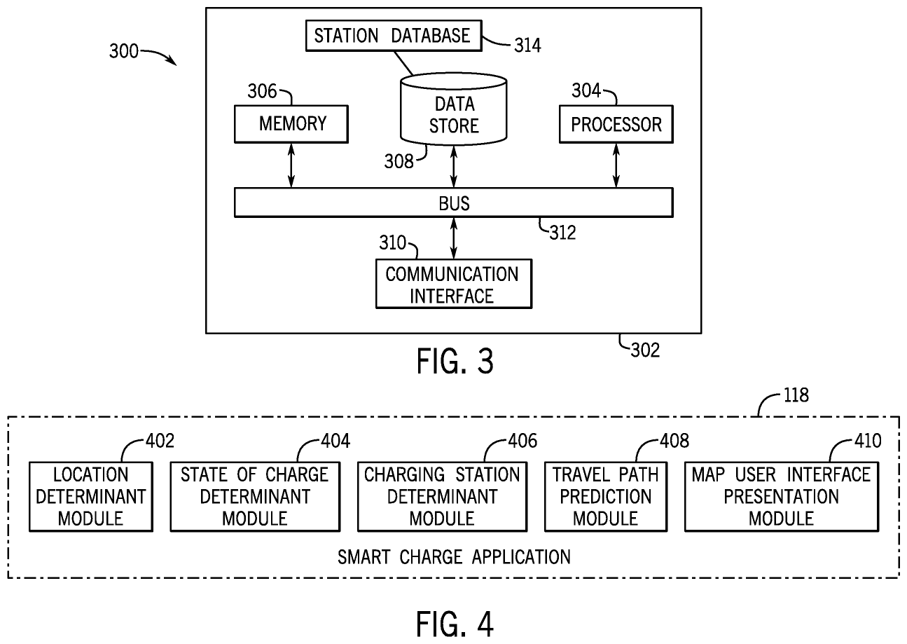

The EV 102 may be operably connected for computer communication to a remote server 108 via a wireless communication network 110. The EV 102 may transmit and receive data (e.g., state of charge data, energy cost data, charging commands/signals) to and from the remote server 108, and vice versa, through the network 110. The remote server 108 may be a remote computing system or a device remote (e.g., off-board) from the EV 102. The system architectures of the EV 102 and the remote server 108 will be discussed in more detail herein with reference to FIG. 2 and FIG. 3.

In the exemplary embodiment of FIG. 1, the system 100 may include one or more charging stations 112 that may connect to the EV 102 via a (respective) charging link 114. The charging station(s) 112 may include charging equipment (not shown) that may replenish the battery 106 of the EV 102 with charging power. Additionally, in some embodiments, the charging station(s) 112 may be operably connected for computer communication with the EV 102 and/or the remote server 108, for example, to transmit and receive data (e.g., charge parameters, charging data and feedback, vehicle system data) to and from the EV 102 and/or the remote server 108. The charging link 114 may be a wired or wireless link to the charging station(s) 112. Computer communication may occur also via the charging link 114 and/or a wired or wireless communication link. In one embodiment, the EV 102, the charging station(s) 112 and/or the charging link 114 may be operably controlled to initiate or terminate charging of the EV 102 from the charging station(s) 112 based on one or more charging schedules that are implemented within the system 100.

In one or more embodiments, the charging station(s) 112 may include charging equipment that may be installed at a residential home or outside a residential home, for example, at a public (e.g., non-networked) or private (e.g., networked) charging station(s). The charging station(s) 112 may include a charging station identification designation (e.g., identification number, serial number, alpha-numeric code, station name) that may be used to identify particular charging stations 112. The charging station(s) 112 may replenish the battery 106 using a charging energy source type that indicates the type of energy the charging station(s) 112 provides. Energy may include clean renewable energy and non-renewable energy. Clean renewable energy may include, solar energy, hydro energy, biomass energy, wind energy, among others. Non-renewable energy may include electricity from a grid source, and in the case of hybrid vehicles, fossil fuels.

In one or more embodiments, the EV 102 may be configured to output charging power to one or more additional electric vehicles 120 that may be physically linked via a vehicle to vehicle charging link (e.g., physical wired link, wireless link) (not shown) with the EV 102. The EV 102 may also be configured to receive charging power to charge the battery 106 of the EV 102 from one or more additional electric vehicles 120 that may be linked via the vehicle to vehicle charging link with the EV 102. Accordingly, the EV 102 and/or the one or more additional electric vehicles 120 may be configured to complete vehicle to vehicle wireless and/or wireline charging that may be completed in real-time without a current utilization of the charging station(s) 112.

In one or more configurations, the EV 102 may be configured of being capable of being fast charged based on fast charging components (not shown) that may be operably connected to the battery 106 and/or that may be included as part of the battery 106. Fast charging may enable the EV 102 to be charged at a faster charging speed (e.g., than a default charging speed) when being charged by a fast charging electric charging equipment (not shown) that may be included at the charging station(s) 112. In particular, fast charging may provide a higher charging voltage from a default/conventional charging voltage (e.g., increase from 240 volts to 480 volts) to more quickly charge the battery 106 of the EV 102. Accordingly, during utilization of fast charging the battery 106 of the EV 102 may be more quickly charged to a particular state of charge level than during the utilization of a conventional electric vehicle charging speed. The charging station(s) 112 may thereby provide a particular charging rate structure that may pertain to the utilization of the conventional electric vehicle charging speed. Additionally, the charging station(s) 112 may provide a particular charging rate structure that may pertain to the utilization of the fast electric vehicle charging speed.

In an exemplary embodiment, the EV 102, the charging station(s) 112, the additional electric vehicles 120, and/or the remote server 108 may receive and transmit data through the network 110 to a charging station computing infrastructure 116 (station computing infrastructure). The station computing infrastructure 116 may include one or more computing devices (not shown) that may communicate with one or more charging station business entities (e.g., charging station corporate owner) that may include utility providers, fuel providers, and/or entities that own and/or operate one or more various types of charging stations, fuel stations, energy stations, and the like.

In one embodiment, the station computing infrastructure 116 may receive perspective and/or real-time price data that may be provided by each respective charging station(s) 112 to communicate different charging rates. The perspective and/or real-time price data may include charging rates during a certain period of time (e.g., hourly, daily, weekly), charging rates to charge the EV 102 at various charging speeds (e.g., conventional electric vehicle charging speed, fast electric vehicle charging speed, charging power levels), charging rates that may be based on a customer rating that may be applied to an operator of the EV 102, and/or charging rates that may be applied to an operator of the EV 102 based on one or more incentives, discounts, and/or credits that may be provided.

In some embodiments, the station computing infrastructure 116 may determine a price per kilowatt-hour of energy (price per kWh) that may be communicated to the EV 102, the remote server 108, and/or the charging station(s) 112 based on utility rates that are received from the one or more energy providers. The price per kWh may include a dynamic value that may change over time based on a time of day, a season, a region, a time zone, etc. For example, each hour of a particular day may include a different price per kWh based on one or more pricing schemes that are implemented by the one or more energy providers.

In an exemplary embodiment, the system 100 may include a smart charge application 118 that may provide various types of enhancements that may be applicable to the charging of the EV 102 and additional electric vehicles. In an exemplary embodiment, the smart charge application 118 may be executed by the EV 102 (e.g., a processor, an electronic control unit) and/or the remote server 108 (e.g., a processor). The smart charge application 118 may include various modules and/or logic (not shown) to provide enhancements to the electric vehicle charging systems from the perspective of the operator of the EV 102, as discussed below.

In particular, the smart charge application 118 may be configured to provide one or more user interfaces to the operator of the EV 102 (and operators of additional electric vehicles 120) that may allow the operator to visually compare charging rates, charging infrastructure, charging queues, and/or additional charging related information that may pertain to various charging stations 112 that may be located within a particular vicinity of a real-time geo-location(s) of the EV 102, a perspective (e.g., predicted) geo-location(s) of the EV 102, and/or a dynamically based determined geo-location(s) that may be based on one or more factors associated with the EV 102.

Referring now to FIG. 2, a schematic view of an illustrative electric vehicle architecture 200, for example the EV 102 of FIG. 1, is shown according to an exemplary embodiment. In particular, the EV 102 may include a vehicle computing device 202 (e.g., a telematics unit, an electronic control unit) with provisions for processing, communicating and interacting with various components of the EV 102 and other components of the system 100. The vehicle computing device 202 may include a processor 204, a memory 206, a data store 208, a position determination device 210 (GPS), a plurality of vehicle systems 212 (e.g., including the electric motor 104, the battery 106) and a communication interface 214. The components of the architecture 200, including the vehicle computing device 202, may be operably connected for computer communication via a bus 216 (e.g., a Controller Area Network (CAN) or a Local Interconnect Network (LIN) protocol bus) and/or other wired and wireless technologies. The vehicle computing device 202 as well as the EV 102 may include other components and systems not shown.

The data store 208 may store application data that may also include data pertaining to the smart charge application 118. In one embodiment, the data store 208 of the EV 102 may include a location log 224 that may optionally (e.g., based on user approval) keep a log of locations at which the EV 102 is driven, parked, and/or charged. The location log 224 may be analyzed by the smart charge application 118 in comparison to point of interest data that may be provided by the station computing infrastructure 116 and stored on the data store 208 of the EV 102 (e.g., pre-stored by the OEM) and/or stored on the data store 308 of the remote server 108 (e.g., pre-stored by a charging station entity). Upon analyzing the location log 224, the smart charge application 118 may be configured to determine one or more travel routines that may be followed by the operator of the EV 102.

The communication interface 214 of the EV 102 may provide software, firmware and/or hardware to facilitate data input and output between the components of the vehicle computing device 202 and other components, networks and data sources. Further, the communication interface 214 may facilitate communication with a display 218 (e.g., head unit display, head up display, dash board display) in the EV 102 and other input/output devices 220, for example, a portable device 222 (e.g., key fob, smart phone) connected to the EV 102.

In some embodiments the portable device 222 may include some or all of the components and functionality of the vehicle computing device 202. Additionally, the communication interface 214 may facilitate communication between the EV 102 and the portable device 222 that may include a display and/or input/output devices (not shown) be used to operate various functions of the EV 102. In one embodiment, the display 218 of the EV 102 and/or the portable device 222 (e.g., through a display screen of the portable device 222) may be utilized to provide one or more user interfaces that may be included as a human machine interface(s) of the smart charge application 118.

Referring now to FIG. 3, a schematic view of an illustrative remote server architecture 300, for example the remote server 108 of FIG. 1, is shown according to an exemplary embodiment. The remote server 108, is located remotely (i.e., off-board) from the EV 102 (as shown in FIG. 1). In some embodiments, the remote server 108 may be maintained by a charging station entity, an Original Equipment Manufacturer (OEM) (e.g., of the EV 102), a utility provider, a regulatory body, among others. In additional embodiments, the remote server 108 may be another type of remote device or supported by a cloud architecture. In FIG. 3, the remote server 108 may include a computing device 302 that may further include a processor 304, a memory 306, a data store 308 and a communication interface 310. The components of the architecture 300, including the computing device 302, may be operably connected for computer communication via a bus 312 and/or other wired and wireless technologies. The computing device 302 as well as the remote server 108 may include other components and systems not shown.

The data store 308 may store application data that may also include data pertaining to the smart charge application 118. In one configuration, the data store 308 may include a customer dataset (not shown) that may include data pertaining to operators of electric vehicles (including the operator of the EV 102) that may utilize the charging station(s) 112. In one configuration, the customer dataset may include a charging schedule that may be associated with the EV 102 utilized by the operator. As discussed below, the smart charge application 118 may allow the operator and/or the charging station entity to update the charging schedule associated with the EV 102 and/or additional electric vehicles 120 that may utilize one or more charging stations 112. Additionally, the customer dataset may include a subjective customer rating (e.g., 1-10 value) that may be applicable to the operators of electric vehicles as determined by the smart charge application 118 and/or one or more charging station entities that may be provided based on one or more factors.

In one configuration, the data store 308 of the remote server 108 may include a station database 314 that may include respective records of charging stations 112 that may be owned and/or operated by one or more charging station entities. The station database 314 may include records that each pertain to particular charging stations 112 that include data that may be pre-updated and/or updated in real-time by one or more charging station entities. In one configuration, the station database 314 may include records that may pertain to particular charging stations 112 and their respective geo-locations (GPS/DGPS coordinates of the charging station(s) 112).

The station database 314 may also include records that may pertain to one or more particular charging stations 112 and one or more pricing schemes that may be implemented by the respective charging stations 112. The one or more pricing schemes may include a price per kWh that may include a dynamic value that may change over time based on a time of day, a season, a region, a time zone, charging power requirements, a charging speed, charging queue place, customer incentives, etc. For example, each hour of a particular day may include a different price per kWh based on one or more pricing schemes that are implemented by the one or more energy providers. Additionally, the one or more pricing schemes may include price per kWh that may be influenced based on a customer rating associated with a respective operator and/or additional factors including, but not limited to, purchase of goods and/or services from the charging station entity and/or additional retailers/service providers. In some embodiments, the station database 314 may also include records that pertain to particular charging stations 112 and current utilization of the charging stations 112. The current utilization of the charging stations 112 may pertain to wait times that may be applicable with respect to the charging of the EV 102.

In one configuration, the communication interface 310 may provide software, firmware and/or hardware to facilitate data input and output between the components of the computing device 302 and other components, networks and data sources. In some embodiments, the communication interface 310 may be used to communicate with the EV 102, the charging station(s) 112, the portable device 222, additional electric vehicles 120, and/or other components of system 100 and architecture 200.

### II. The Smart Charge Application and Related Methods

The smart charge application 118 and its components will now be discussed in more detail according to an exemplary embodiment and with continued reference to FIGS. 1-3. In one or more embodiments, the smart charge application 118 may be executed by the vehicle computing device 202 of the EV 102 and/or the computing device 302 of the remote server 108. In an alternate embodiment, the smart charge application 118 may be executed by a processor (not shown) of the portable device 222 that may be used by the operator of the EV 102.

In one or more configurations, data may be sent or received from the smart charge application 118 to the components of the EV 102, the remote server 108, the charging station(s) 112, the charging link 114, the portable device 222, and/or the additional electric vehicles 120. For example, commands from the smart charge application 118 may be sent to the charging station(s) 112 and/or the charging link 114 to initiate or terminate charging of the EV 102 during one or more periods of time based on the one or more factors and/or the one or more charging schedules.

In an exemplary embodiment, the smart charge application 118 may include one or more user input interfaces and/or input means (e.g., buttons) that may be presented via the display 218, presented via the portable device 222, and or included within the EV 102 and/or on the portable device 222. In one embodiment, the one or more user input interfaces and/or input means may include user interface inputs that may be utilized by an individual (e.g., the operator of the EV 102) to enable or disable the presentation of one or more user interface graphics that may be presented by the smart charge application 118. Additionally, the one or more user input interfaces and/or input means may include user interface inputs that may be utilized by an individual to enable or disable one or more smart charging functions provided by the smart charge application 118.

As discussed above, the smart charge application 118 may be configured to provide one or more user interfaces to the operator of the EV 102 (and operators of additional electric vehicles) that may allow the operator to visually compare charging rates, charging infrastructure, charging queues, and/or additional charging related information that may pertain to various charging stations 112 that may be located within a particular vicinity of a current (e.g., real-time) geo-location of the EV 102, a perspective (e.g., predicted) geo-location(s) of the EV 102, and/or a dynamically based determined geo-location(s) that may be based on one or more factors associated with the EV 102.

FIG. 4 is a schematic view of a plurality of modules 402-410 of the smart charge application 118 that may execute computer-implemented instructions for presenting electric vehicle charging options according to an exemplary embodiment of the present disclosure. In an exemplary embodiment, the plurality of modules 402-410 may include a location determinant module 402, a state of charge determinant module (SOC determinant module) 404, a charging station determinant module 406, a travel path prediction module 408, and a map user interface presentation module (map presentation module) 410. It is appreciated that the smart charge application 118 may include one or more additional modules and/or sub-modules that are included in lieu of the modules 402-410.

In one or more configurations, the location determinant module 402 of the smart charge application 118 may be configured to determine the current geo-location of the EV 102 (e.g., current GPS/DGPS coordinates of the EV 102). In particular, the location determinant module 402 may be configured to communicate with the GPS 210 of the EV 102 to determine the current geo-location of the EV 102 at one or more points in time. In some embodiments, the location determinant module 402 may be configured to store the one or more geo-locations of the EV 102 determined at one or more points in time within the data store 208 of the vehicle computing device 202 and/or the data store 308 of the remote server 108.

In an exemplary embodiment, the SOC determinant module 404 may be configured to determine a current state of charge (SOC) (e.g., charging level) of the battery 106 of the EV 102. In one configuration, the SOC determinant module 404 may be configured to communicate with the processor 204 of the vehicle computing device 202 to determine the current SOC of the battery 106 of the EV 102. In one embodiment, the processor 204 may be configured to communicate with a micro-processor (not shown) that may be included as part of electrical circuitry of the battery 106 to determine a current SOC of the battery 106.

In one or more embodiments, upon determining one or more geo-locations of the EV 102, the location determinant module 402 may be configured to communicate respective data to the charging station determinant module 406. In one embodiment, upon receiving data pertaining to a current geo-location of the EV 102, the charging station determinant module 406 may be configured to determine geo-locations of one or more charging stations 112 that may be located within a predetermined distance (e.g. 5 miles in one or more directions) of the current geo-location of the EV 102.

In particular, the charging station determinant module 406 may be configured to access the station database 314 stored upon the data store 308 of the remote server 108. As discussed, the station database 314 may include records that each pertain to particular charging stations 112 that include data that may be pre-updated and/or updated in real-time by one or more charging station entities. Such records may pertain to particular charging stations 112 and their respective geo-locations. Accordingly, the charging station determinant module 406 may be configured to access and query the station database 314 to determine one or more charging stations 112 that may be located within a predetermined distance (e.g., 5 miles) of the current geo-location of the EV 102 or within a predetermined distance of a type of amenity or selected point of interest location.

In another embodiment, the SOC determinant module 404 may be configured to determine the SOC of the battery 106 of the EV 102 at one or more points in time based on communication with the processor 204 of the vehicle computing device 202 of the EV 102. The SOC determinant module 404 may be additionally configured to analyze the current geo-location of the EV 102 and determine a remaining distance that the EV 102 is capable of traveling. The remaining distance may be determined based on analyzing the current SOC of the battery 106, an average speed of the EV 102, and/or one or more road types (e.g., local, highway, road grades) that may be located within a vicinity of the current geo-location of the EV 102. Upon determining the current SOC and remaining distance that the EV 102 may travel at the average speed of the EV 102, the SOC determinant module 404 may communicate respective data to the charging station determinant module 406.

In one embodiment, the charging station determinant module 406 may be configured to analyze the current geo-location of the EV 102 as determined and communicated by the location determinant module 402 in addition to the current SOC and remaining distance that the EV 102 may travel as determined and communicated by the SOC determinant module 404. The charging station determinant module 406 may thereby be configured to determine one or more charging stations 112 that may be located within a distance that the EV 102 may travel to reach based the charging station(s) on the current geo-location of the EV 102, the current SOC of the battery 106 of the EV 102, and/or one or more road types (e.g., local, highway, road grades) that may be located within a vicinity of the current geo-location of the EV 102.

In another embodiment, the charging station determinant module 406 may be configured to determine the location of additional electric vehicles 120 that may be configured to provide charging power to charge the battery 106 of the EV 102. As discussed above, the additional electric vehicles 120 may additionally or alternatively be configured to receive charging power from the EV 102. In particular, the charging station determinant module 406 may be configured to communicate with GPS devices (not shown) of the additional electric vehicles 120 to determine respective geo-locations of the additional electric vehicles 120.

In one configuration, upon determining the respective geo-locations of the additional electric vehicles 120 the charging station determinant module 406 may be configured to analyze the current geo-location of the EV 102 as determined based on communication received from the location determinant module 402. The charging station determinant module 406 may be configured to compare the current geo-location of the EV 102 to the respective geo-locations of the additional electric vehicles 120 to determine one or more additional electric vehicles 120 that may be located within a predetermined distance of the EV 102.

In another configuration, upon determining the respective geo-locations of the additional electric vehicles 120, the charging station determinant module 406 may be configured to analyze the current geo-location of the EV 102 and the current SOC of the battery 106 of the EV 102, as determined based on communication received from the SOC determinant module 404. The charging station determinant module 406 may be configured to compare the current geo-location of the EV 102 to the respective geo-locations of the additional electric vehicles 120. Additionally, the charging station determinant module 406 may analyze the remaining distance that the EV 102 may travel as determined and communicated by the SOC determinant module 404 to thereby determine one or more additional electric vehicles 120 that may be located within a distance that the EV 102 may travel to reach the charging station(s) 112 based on the current geo-location of the EV 102, the current SOC of the battery 106 of the EV 102, and/or one or more road types that may be located within a vicinity of the current geo-location of the EV 102. The charging station determinant module 406 may be configured to communicate data determined by the module 406 to the map presentation module 410 of the smart charge application 118.

In an exemplary embodiment, the travel path prediction module 408 of the smart charge application 118 may be configured to predict one or more perspective travel paths of the EV 102 based on the determination and analysis of one or more travel routines that may be followed by the operator of the EV 102. As discussed above, the location log 224 stored on the data store 208 of the vehicle computing device 202 may include a log of locations at which the EV 102 is driven, parked, and/or charged. In one configuration, the travel path prediction module 408 may analyze the location log 224 to determine one or more point of interest locations that may be frequently and/or routinely traveled to by the EV 102. In particular, the travel path prediction module 408 may analyze point of interest data (not shown) that may be stored on the data store 208 of the vehicle computing device 202 and/or the data store 308 of the remote server 108 to determine one or more points of interest locations that may be frequently and/or routinely traveled to by the EV 102.

Upon analyzing the location log 224, the travel path prediction module 408 may be configured to determine one or more travel routines that may be followed by the operator of the EV 102. In some configurations, the one or more travel routines may be analyzed through a neural network (not shown) to provide computer/machine based/deep learning techniques to determine whether a particular trip of the EV 102 is a routine trip or non-routine trip based on the analysis of data provided by the GPS 210.

In one embodiment, the travel path prediction module 408 may analyze the current geo-location of the EV 102 at one or more points in time with respect a particular timeframe of utilization of the EV 102 and one or more routine trips that may be determined to thereby predict one or more perspective travel routes that may be utilized by the EV 102 to reach one or more points of interest locations that may be frequently and/or routinely traveled to by the EV 102. The travel path prediction module 408 may thereby communicate data pertaining to the perspective travel routes to the charging station determinant module 406.

In one embodiment, upon receiving data pertaining to one or more perspective travel routes of the EV 102, the charging station determinant module 406 may be configured to access and query the station database 314 to determine one or more charging stations 112 that may be located within a predetermined distance of one or more perspective travel paths that are predicted to be utilized by the EV 102 based on one or more travel routines of the operator of the EV 102.

In one embodiment, the travel path prediction module 408 may be configured to communicate one or more perspective travel paths that are predicted to be utilized by the EV 102 to the SOC determinant module 404. The SOC determinant module 404 may be configured to analyze the current SOC of the battery 106 of the EV 102 and the one or more perspective travel paths to predict one or more perspective SOC levels of the battery 106 during perspective travel of the EV 102. The one or more perspective SOC levels of the battery 106 may be based on the current SOC of the battery 106, an average speed of the EV 102, and/or one or more road types (e.g., local, highway, road grades) of the one or more perspective travel paths of the EV 102 as predicted by the travel path prediction module 408. Upon determining the perspective SOC levels of the battery 106, the SOC determinant module 404 may communicate data pertaining to the one or more perspective travel paths of the EV 102 and the one or more associated perspective SOC levels of the battery 106 to the charging station determinant module 406.

In one configuration, the charging station determinant module 406 may be configured to analyze the one or more perspective travel paths of the EV 102 and the associated perspective SOC levels of the battery 106 of the EV 102. The charging station determinant module 406 may thereby access and query the station database 314 to determine one or more charging stations 112 that may be located within a distance that the EV 102 may travel to reach based on the one or more perspective travel paths of the EV 102 and the associated perspective SOC level(s) of the battery 106 of the EV 102. Accordingly, the charging station determinant module 406 may determine one or more charging stations 112 that may be located on or within a predetermined distance of one or more perspective travel paths of the EV 102 and that may be located within a distance that is reachable by the EV 102 based on associated perspective SOC levels of the battery 106. As discussed above, the charging station determinant module 406 may be configured to communicate data determined by the module 406 to the map presentation module 410 of the smart charge application 118.

In an exemplary embodiment, the map presentation module 410 of the smart charge application 118 may be configured to present one or more charging station map user interfaces that present data determined and/or predicted by the modules 402-408, as discussed above. In particular, the charging station map interface(s) may include a map that may pin point a current geo-location of the EV 102, a perspective geo-location of the EV 102 on one or more perspective travel paths of the EV 102, a type of amenity, and/or a selected point of interest.

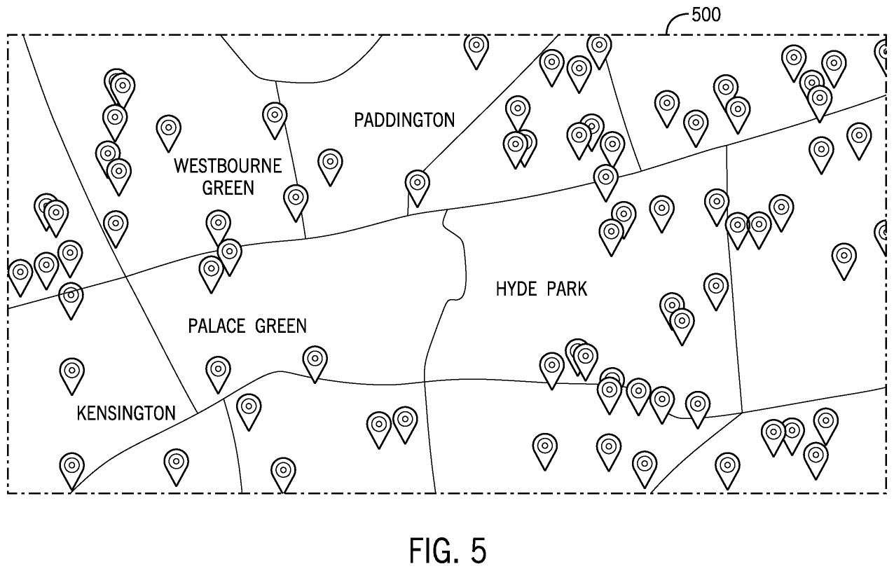

As shown in FIG. 5, an illustrative example of a charging station map user interface 500 according to an exemplary embodiment of the present disclosure, the charging station map user interface 500 may be presented with pin points that are associated with respective charging stations 112. The charging station map user interface 500 may be presented through the display 218 of the EV 102 and/or a display of the portable device 222. As discussed below, the map presentation module 410 may present the charging station map user interface 500 to pin point a current geo-location of the EV 102, one or more perspective geo-locations of the EV 102, and the geo-location(s) of one or more charging stations 112 that may be located within the predetermined distance of the EV 102, within a predetermined distance of one or more perspective pathways of the EV 102, near one or more points of interest at which one or more routine activities may take place, and/or at one or more locations at which the EV 102 may need to be charged to maintain a sufficient SOC to be utilized complete one or more remaining routine activities and/or non-routine activities.

In some configurations, the charging station map user interface 500 may be presented in two-dimensional format (as shown in FIG. 5). In additional configurations, the charging station map user interface 500 may be converted to a three-dimensional format, a street-view format, a first person point of view format, a satellite view format, and the like based on the receipt of a respective user interface input.

The charging station map user interface 500 may be selectively enabled or disabled based on the receipt of a respective user interface input. In some configurations, the charging station map user interface 500 may be enabled based on a predetermined SOC level of the battery 106 of the EV 102 (e.g., 30% remaining SOC) and/or a user based enablement setting that may be associated with the geo-location of the EV 102 and/or a particular timeframe (e.g., particular day of the week). Upon enablement, the charging station map user interface 500 may be initially presented in a format that may show an area that may be included within a predetermined distance or user selected distance of the geo-location of the EV 102. The charging station map user interface 500 may be configured to be zoomed in or zoomed out to show a smaller area or larger area based on the adjustment of the distance of the geo-location of the EV 102 that is to be presented. Accordingly, the operator of the EV 102 may be able to view data associated with one or more charging stations 112 that may be located at a variable distance from the current geo-location of the EV 102 and/or one or more perspective travel paths of the EV 102.

In one embodiment, the operator may selectively input one or more charging stations 112 and/or charging station entities that own and/or operate particular charging stations 112 as favorites. Such favorites may be shown as highlighted or accompanied with a user interface graphic (e.g., star) that may allow the operator to easily identify them on the charging station map user interface 500. Additionally, the operator may selectively input one or more charging stations 112 and/or charging station entities that own and/or operate particular charging stations 112 as prohibited. Such prohibited charging stations 112 and/or charging stations 112 that are owned and/or operated by prohibited charging station entities may not be pin pointed on the charging station map user interface 500.

In additional embodiments, the operator may selectively input threshold preferences related to price schemes, queue/wait times, price incentives, charging types, and the like that may be utilized to pin point one or more charging stations 112 on the charging station map user interface 500. For example, the operator may choose a threshold queue/wait time threshold preference of “15 minutes” to highlight charging stations 112 that may include a 15 minute or less queue wait time. Accordingly, the charging station map user interface 500 may be selectively customized to pin point one or more charging stations 112 that may apply with respect to the threshold preferences. The one or more charging stations 112 may be shown as highlighted or accompanied with a user interface graphic (e.g., clock symbol) that may allow the operator to easily identify them on the charging station map user interface 500. In other embodiments, one or more charging stations 112 that may not apply with respect to the threshold preferences may be selectively hidden based on a user interface input received by the operator. It is to be appreciated that one or more charging stations 112 may be pin pointed, highlighted, accompanied with user interface graphics, and/or hidden based on user interface inputs that may be associated with various user preferences. The interface graphics may be based on a type of amenity available at or near a charging station. For example, a coffee cup icon may be illustrated near a charging station with hot beverages available.

Specific embodiments of the presentation of the map user interface(s) will now be described. With continued reference to FIG. 1, in one embodiment the map presentation module 410 may present the charging station map interface(s) as a map that may additionally pin point one or more charging stations 112 that may be determined to be within the (default) predetermined distance of the EV 102, as determined by the charging station determinant module 406. In another embodiment, the charging station map interface(s) may also or alternatively pin point one or more charging stations 112 that may be determined to be located within a distance that the EV 102 may travel to reach the charging station(s) 112 based on the current geo-location of the EV 102, the current SOC of the battery 106 of the EV 102, and/or one or more road types that may be located within a vicinity of the current geo-location of the EV 102.

In some embodiments, the charging station map interface(s) may pin point one or more charging stations 112 that may be located within a predetermined distance of one or more perspective travel paths that are predicted to be utilized by the EV 102 based on one or more travel routines of the operator of the EV 102, as determined by the charging station determinant module 406. In additional embodiments, the charging station map interface(s) may additionally or alternatively pin point one or more charging stations 112 that may be located on or near one or more perspective travel paths of the EV 102 as predicted by the travel path prediction module 408 and that may be located within a distance that is reachable by the EV 102 based on associated perspective SOC levels of the battery 106 as predicted by the SOC determinant module 404. In some embodiments, the charging station map interface(s) may pin point one or more charging stations 112 that may be located within a predetermined distance of one or more amenities.

In one embodiment, the map presentation module 410 may be configured to communicate with the station computing infrastructure 116 to determine one or more price schemes that may be implemented by respective charging stations 112 that are presented as pin pointed. The map presentation module 410 may be configured to present one or more price schemes and/or a summary of pricing that may be applicable to each of the respective charging stations 112 that are presented as pin pointed. The one or more charging stations 112 may be presented with an estimated cost to charge the EV 102 based on a current or perspective SOC of the EV 102 at one or more charging stations 112 based on respective price schemes. In some configurations, the map presentation module 410 may be configured to present one or more user interface input links that may be inputted by the operator of the EV 102 to determine additional pricing information and/or trends that may be applicable to the respective charging stations 112.

In another embodiment, the map presentation module 410 may be configured to communicate with the station computing infrastructure 116 to determine one or more queues/wait times (e.g., queues of electric vehicles to be charged) that are associated with respective charging stations 112. The one or more queues may be analyzed to determine respective wait times to charge the EV 102 if the EV 102 were to be added to a respective queue(s). Accordingly, the smart charge application 118 may present the charging station map user interface that includes a map that may pin point one or more charging stations 112 that include queue and wait time details that may pertain to each of the respective charging stations 112. In one configuration, the smart charge application 118 may present a user interface input that may be associated to each of the one or more charging stations 112 that may be selected by the operator to add or remove the EV 102 from a queue of a respective charging station(s) 112. Accordingly, the charging station map user interface(s) may be utilized by the operator to schedule the charging of the EV 102 at one or more charging stations(s) 112 at one or more points in time.

In some configurations, the map presentation module 410 may be configured to communicate with the station computing infrastructure 116 to determine one or more charging stations 112 that may be equipped to provide fast charging capabilities. The map presentation module 410 may be configured to present one or more of the charging stations 112 that may be equipped to provide fast charging capabilities as pin pointed on the charging station map user interface. The charging station map user interface may be presented with respective user interface inputs that may be selected to add the EV 102 to a queue of one or more charging stations that may be configured to provide fast charging capabilities to fast charge the EV 102.

In one embodiment, the map presentation module 410 may be configured to communicate with the station computing infrastructure 116 to receive incentive pricing schemes that may be provided by one or more charging station entities and/or one or more particular charging stations 112. In another embodiment, the map presentation module 410 may communicate with remote server 108 to receive incentive pricing schemes that may be stored within the station database 314 that may include records that each pertain to particular charging stations 112 and/or charging station entities as populated by one or more charging station entities. In some circumstances, the incentive pricing schemes may be provided by one or more charging station entities to incentivize customers to charge their vehicles at one or more off-peak timeframes where a demand for charging may be below an average amount. For example, many customers may tend to charge electric vehicles during hours at night with in-home charging stations (not shown). Accordingly, the incentive pricing schemes provided may be provided by one or more charging station entities to incentivize customers to charge their vehicles at one or more off-peak timeframes at one or more charging stations 112 that may be owned and/or operated by the one or more charging station entities and that are available to the public.

In some embodiments, the incentive pricing schemes may be provided by one or more charging station entities to incentivize customers to charge their vehicles at one or more off-peak timeframes at one or more charging stations 112 that may be publically accessible and that may be located within the predetermined distance of the EV 102, near one or more perspective pathways of the EV 102, near one or more points of interest at which one or more routine activities may take place, and/or at one or more locations at which the EV 102 may need to be charged to maintain a sufficient SOC to complete one or more remaining routine activities and/or non-routine activities.

In some configurations, the map presentation module 410 may also present the charging station map user interface that may include a map that may pin point a current geo-location of the EV 102, one or more perspective geo-locations of the EV 102, and the geo-location(s) of one or more charging stations 112 that may be located within the predetermined distance of the EV 102, near one or more perspective pathways of the EV 102, near one or more points of interest at which one or more routine activities may take place, and/or at one or more locations at which the EV 102 may need to be charged to maintain a sufficient SOC to complete one or more remaining routine activities. The one or more charging stations 112 may be presented with an estimated cost to charge the EV 102 based on a current or perspective SOC of the EV 102 at one or more charging stations 112 that implement the incentive pricing schemes. Accordingly, certain attributes pertaining to a time of day, pricing schemes, retail based discounts, credits, and/or offers may be presented to the operator through the charging station map user interface to provide details with respect to one or more charging stations 112 that may provide incentives to the operator.

In one or more embodiments, the map presentation module 410 may be configured to communicate with the charging station determinant module 406 to determine the geo-location(s) of one or more additional electric vehicles 120 that may be configured provide charging power to charge the battery 106 of the EV 102. As discussed above, the additional electric vehicles 120 may additionally or alternatively be configured to receive charging power from the EV 102.

As discussed above, upon determining the respective geo-locations of the additional electric vehicles 120 the charging station determinant module 406 may be configured to analyze the current geo-location of the EV 102 as determined based on communication received from the location determinant module 402. The charging station determinant module 406 may be configured to compare the current geo-location of the EV 102 to the respective geo-locations of the additional electric vehicles 120 to determine one or more additional electric vehicles 120 that may be located within a predetermined distance of the EV 102.

The map presentation module 410 may thereby receive respective data from the charging station determinant module 406 and may present the charging station map user interface(s) with the one or more pin points that pin point the current geo-locations of one or more additional electric vehicles 120 that may be located within a predetermined distance of the EV 102. The map presentation module 410 may present a user interface input that may be associated to each of the one or more additional electric vehicles 120 that may be selected by the operator to send and/or receive vehicle to vehicle communications with one or more additional electric vehicles 120 through the communication interface 214 of the vehicle computing device 202 to reserve vehicle to vehicle charging at one or more particular user interface selectable geo-locations that are presented on the charging station map user interface(s). In one embodiment, the interface selectable geo-locations may be displayed as reservation selection inputs that the EV operator can select to reserve the at least one charging station for charging the electric vehicle. Selecting one or more particular user interface selectable geo-locations that are presented on the charging station map user interface may allow the EV operator to reserve a time or position to charge. Accordingly, the charging station map user interface(s) may be utilized by the operator to reserve vehicle to vehicle charging of the EV 102 or from the EV 102 with one or more additional electric vehicles 120 at one or more points in time.

In some circumstances, the operator of the EV 102 and/or operators of respective additional electric vehicles 120 may set a charging rate to implement vehicle to vehicle charging through a vehicle charging rate user interface provided by the smart charge application 118. In other words, the operator(s) of the additional electric vehicle(s) 120 may set a charging rate to provide charging power to charge the EV 102 through vehicle to vehicle charging. Similarly, the operator of the EV 102 may set a charging rate to provide charging power to charge one or more additional electric vehicles 120 through vehicle to vehicle charging.

Upon the charging rates being set, the charging rate(s) may be stored upon the data store 308 of the remote server 108. In one embodiment, the map presentation module 410 may be configured to access the data store 308 to retrieve the charging rate associated with one or more respective additional electric vehicles 120 that may be located within a predetermined distance of the EV 102. The map presentation module 410 may thereby present the map user interface(s) with the one or more pin points that pin point the locations of one or more additional electric vehicles 120 that may be located within a predetermined distance of the EV 102 in addition to respective charging rates that may be charged by the respective additional electric vehicles 120.

It is to be appreciated that the map presentation module 410 may present the charging station map user interface(s) in a variety of formats that may be presented with graphics detailed within one or more of the aforementioned embodiments. Accordingly, the charging station map user interface(s) may be presented to provide various levels of information that may pertain to one or more charging stations 112 and/or additional electric vehicles 120 that may be potentially utilized to charge the EV 102 in or more manners. It is also to be appreciated that the map presentation module 410 may present the charging station map user interface(s) with additional contemplated information that may be related to utility costs, electric charging costs, a price per kWh of charging power that may include a dynamic value that may change over time based on a time of day, a season, a region, a time zone, etc., additional queue/wait time information, charging station/charging station entity incentives, and/or additional information that may be presented to the operator of the EV 102.

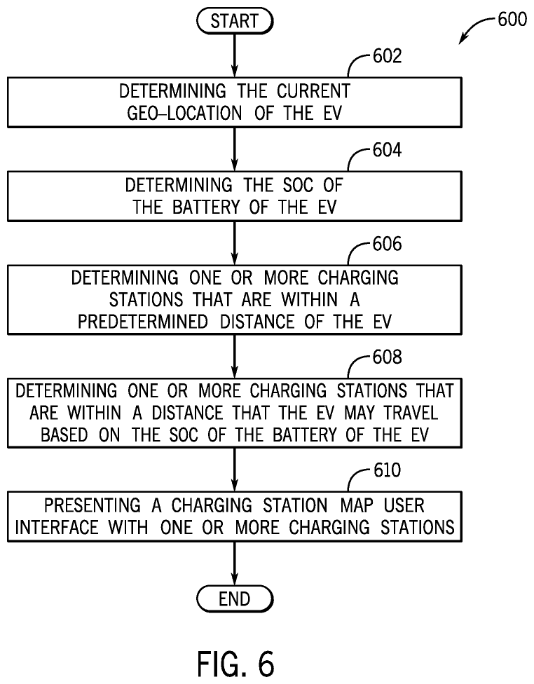

FIG. 6 is a process flow diagram of a method 600 for presenting the charging station map user interface with one or more charging stations based on the current geo-location of the EV 102 and the SOC of the battery 106 of the EV 102 according to an exemplary embodiment of the present disclosure. FIG. 6 will be described with reference to the components of FIG. 1, FIG. 2, FIG. 3, and FIG. 4, through it is to be appreciated that the method 600 of FIG. 6 may be used with additional and/or alternative system components. The method 600 may begin at block 602, wherein the method 600 may include determining the current geo-location of the EV 102.

In an exemplary embodiment, the location determinant module 402 may be configured to communicate with the GPS 210 of the EV 102 to determine the current geo-location of the EV 102 at one or more points in time. In some embodiments, the location determinant module 402 may be configured to store one or more geo-locations of the EV 102 as determined at one or more points in time within the data store 208 of the vehicle computing device 202 and/or the data store 308 of the remote server 108.

The method 600 may proceed to block 604, wherein the method 600 may include determining the SOC of the battery 106 of the EV 102. As discussed above, the SOC determinant module 404 may be configured to determine the current SOC of the battery 106 of the EV 102. In one configuration, the SOC determinant module 404 may be configured to communicate with the processor 204 of the vehicle computing device 202 to determine the current SOC of the battery 106 of the EV 102. In one embodiment, the processor 204 may be configured to communicate with a micro-processor (not shown) that may be included as part of electrical circuitry of the battery 106 to determine a current SOC of the battery 106. The SOC determinant module 404 may be additionally configured to analyze the current geo-location of the EV 102 and determine a remaining distance that the EV 102 is capable of traveling. The remaining distance may be determined based on analyzing the current SOC of the battery 106, an average speed of the EV 102, and/or one or more road types (e.g., local, highway, road grades) that may be located within a vicinity of the current geo-location of the EV 102. Upon determining the current SOC and remaining distance that the EV 102 may travel at the average speed of the EV 102, the SOC determinant module 404 may communicate respective data to the charging station determinant module 406.

The method 600 may proceed to block 606 wherein the method 600 may include determining one or more charging stations 112 that are within a predetermined distance of the EV 102. In one embodiment, upon receiving data pertaining to a current geo-location of the EV 102, the charging station determinant module 406 may be configured to determine geo-locations of one or more charging stations 112 that may be located within the predetermined distance of the current geo-location of the EV 102. In particular, the charging station determinant module 406 may be configured to access and query the station database 314 to determine one or more charging stations 112 that may be located within the predetermined distance (e.g., 5 miles) of the current geo-location of the EV 102. Upon determining the one or more charging stations 112 that may be located within the predetermined distance of the current geo-location of the EV 102, the charging station determinant module 406 may communicate data pertaining to the one or more charging stations 112 to the map presentation module 410 of the smart charge application 118.

The method 600 may proceed to block 608 wherein the method 600 may include determining one or more charging stations 112 that are within a distance that the EV 102 may travel based on the SOC of the battery 106 of the EV 102. In one embodiment, the charging station determinant module 406 may be configured to analyze the current geo-location of the EV 102 as determined and communicated by the location determinant module 402 in addition to the current SOC and remaining distance that the EV 102 may travel as determined and communicated by the SOC determinant module 404. The charging station determinant module 406 may thereby be configured to access and query the station database 314 to determine one or more charging stations 112 that may be located within a distance that the EV 102 may travel to reach the charging station(s) 112 based on the current geo-location of the EV 102, the current SOC of the battery 106 of the EV 102, and/or one or more road types (e.g., local, highway, road grades) that may be located within a vicinity of the current geo-location of the EV 102. Upon determining the one or more charging stations 112 that may be located within a distance that the EV 102 may travel based on the SOC of the battery 106 of the EV 102, the charging station determinant module 406 may communicate data pertaining to the one or more charging stations 112 to the map presentation module 410 of the smart charge application 118.

The method 600 may proceed to block 610, wherein the method 600 may include presenting a charging station map user interface with one or more charging stations 112. In one embodiment the map presentation module 410 may present the charging station map interface through the display unit of the EV 102 and/or through the display of the portable device 222. The charging station map interface may be presented as a map that may pin point one or more charging stations 112 that may be determined to be within the predetermined distance of the EV 102, as determined by the charging station determinant module 406. Additionally, the charging station map interface may pin point one or more charging stations 112 that may be determined to be located within a distance that the EV 102 may travel to reach the charging station(s) 112 based on the current geo-location of the EV 102, the current SOC of the battery 106 of the EV 102, and/or one or more road types that may be located within a vicinity of the current geo-location of the EV 102.

The charging station map interface may present information that may pertain to the one or more charging stations 112 that may be pin pointed. Such information may include, but may not be limited to, perspective and/or real-time price data, information regarding queues and/or wait times that are associated to respective charging stations 112, information regarding fast charging capabilities, and/or pricing incentives that may be provided by the respective charging stations 112.

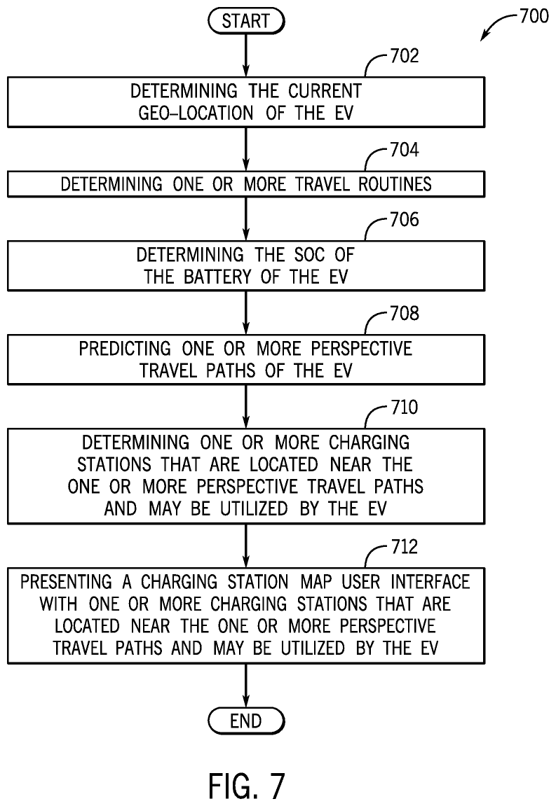

FIG. 7 is a process flow diagram of a method 700 for presenting the charging station map user interface with one or more charging stations that are located near one or more perspective travel paths that may be utilized by the EV 102 according to an exemplary embodiment of the present disclosure. FIG. 7 will be described with reference to the components of FIG. 1, FIG. 2, FIG. 3, and FIG. 4, through it is to be appreciated that the method 700 of FIG. 7 may be used with additional and/or alternative system components. The method 700 may begin at block 702, wherein the method 700 may include determining the current geo-location of the EV 102.

In an exemplary embodiment, the location determinant module 402 may be configured to communicate with the GPS 210 of the EV 102 to determine the current geo-location of the EV 102 at one or more points in time. In some embodiments, the location determinant module 402 may be configured to store the one or more geo-locations of the EV 102 determined at one or more points in time within the data store 208 of the vehicle computing device 202 and/or the data store 308 of the remote server 108.

The method 700 may proceed to block 704, wherein the method 700 may include determining one or more travel routines. As discussed above, the location log 224 stored on the data store 208 of the vehicle computing device 202 may include a log of locations at which the EV 102 is driven, parked, and/or charged. In one configuration, the travel path prediction module 408 may analyze the location log 224 to determine one or more point of interest locations that may be frequently and/or routinely traveled to by the EV 102. In particular, the travel path prediction module 408 may analyze point of interest data (not shown) that may be stored on the data store 208 of the vehicle computing device 202 and/or the data store 308 of the remote server 108 to determine one or more points of interest locations that may be frequently and/or routinely traveled to by the EV 102.

Upon analyzing the location log 224, the travel path prediction module 408 may be configured to determine one or more travel routines that may be followed by the operator of the EV 102. In some configurations, the one or more travel routines may be analyzed through the neural network to provide computer/machine based/deep learning techniques to determine whether a particular trip of the EV 102 is a routine trip or non-routine trip based on the analysis of data provided by the GPS 210.

The method 700 may proceed to block 706, wherein the method 700 may include determining the SOC of the battery of the EV 102. In one configuration, the SOC determinant module 404 may be configured to communicate with the processor 204 of the vehicle computing device 202 to determine the current SOC of the battery 106 of the EV 102. In one embodiment, the processor 204 may be configured to communicate with a micro-processor (not shown) that may be included as part of electrical circuitry of the battery 106 to determine a current SOC of the battery 106. The SOC determinant module 404 may be additionally configured to analyze the current geo-location of the EV 102 and determine a remaining distance that the EV 102 is capable of traveling. The remaining distance may be determined based on analyzing the current SOC of the battery 106, an average speed of the EV 102, and/or one or more road types (e.g., local, highway, road grades) that may be located within a vicinity of the current geo-location of the EV 102. Upon determining the current SOC and remaining distance that the EV 102 may travel at the average speed of the EV 102, the SOC determinant module 404 may communicate respective data to the travel path prediction module 408 and/or the charging station determinant module 406.

The method 700 may proceed to block 708, wherein the method 700 may include predicting one or more perspective travel paths of the EV 102. In one embodiment, the travel path prediction module 408 may analyze the current geo-location of the EV 102 at one or more points in time with respect a particular timeframe of utilization of the EV 102, the current SOC of the battery 106 of the EV, the remaining distance that the EV 102 may travel, and/or one or more routine trips that may be determined (at block 704) to thereby predict one or more perspective travel paths (e.g., routes, roads, highways, etc.) that may be utilized by the EV 102 to reach one or more points of interest locations that may be frequently and/or routinely traveled to by the EV 102. The travel path prediction module 408 may thereby communicate data pertaining to the perspective travel routes to the charging station determinant module 406.

The method 700 may proceed to block 710, wherein the method 700 may include determining one or more charging stations 112 that are located near one or more perspective travel paths and that may be utilized by the EV 102. In one embodiment, upon receiving data pertaining to one or more perspective travel routes of the EV 102, the charging station determinant module 406 may be configured to access and query the station database 314 to determine one or more charging stations 112 that may be located within a predetermined distance of one or more perspective travel paths that are predicted to be utilized by the EV 102 based on one or more travel routines of the operator of the EV 102, the current geo-location of the EV 102, the current SOC of the EV 102, and/or the remaining distance that the EV 102 may travel.

Accordingly, the charging station determinant module 406 may determine one or more charging stations 112 that may be located on or near one or more perspective travel paths of the EV 102 as predicted by the travel path prediction module 408 and that may be located within a distance that is reachable by the EV 102 based on associated perspective SOC levels of the battery 106 that may be predicted by the SOC determinant module 404, as discussed above. In one embodiment, the charging station determinant module 406 may be configured to communicate data associated with the one or more charging stations 112 that are determined to be located near the one or more perspective travel paths to the map presentation module 410 of the smart charge application 118.

The method 700 may proceed to block 712, wherein the method 700 may include presenting a charging station map user interface with one or more charging stations 112 that are located near the one or more perspective travel paths and may be utilized by the EV 102. In an exemplary embodiment, the map presentation module 410 of the smart charge application 118 may be configured to present one or more charging station map user interfaces that may present the map of one or more charging stations 112 that are determined to be located near the one or more perspective travel paths and that may be utilized by the EV 102. In particular, the one or more charging stations 112 that are determined to be located near the one or more perspective travel paths and that may be utilized by the EV 102 may be presented as pin pointed to allow the operator to determine the location of the charging station(s) 112 with respect to the current or perspective (predicted) locations of the EV 102.

In one or more embodiments, the charging station map interface may present information that may pertains to the one or more charging stations 112 that may be pin pointed. Such information may include, but may not be limited to, perspective and/or real-time price data, information regarding queues and/or wait times that are associated to respective charging stations 112, information regarding fast charging capabilities, and/or pricing incentives that may be provided by the respective charging stations 112.

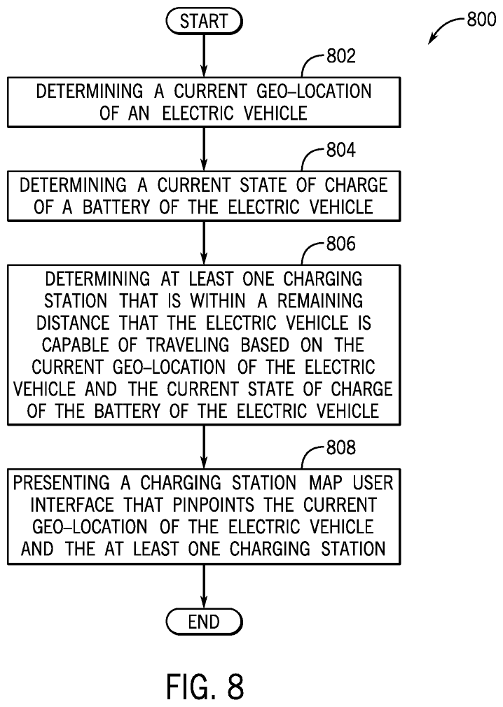

FIG. 8 is a process flow diagram of a method 800 for presenting electric vehicle charging options according to an exemplary embodiment of the present disclosure. FIG. 8 will be described with reference to the components of FIG. 1, FIG. 2, FIG. 3, and FIG. 4, through it is to be appreciated that the method 800 of FIG. 8 may be used with additional and/or alternative system components. The method 800 may begin at block 802, wherein the method 800 may include determining a current geo-location of an EV 102.

The method 800 may proceed to block 804, wherein the method 800 may include determining a current state of charge of a battery 106 of the EV 102. The method 800 may proceed to block 806, wherein the method 800 may include determining at least one charging station 112 that is within a remaining distance that the EV 102 is capable of traveling based on the current geo-location of the EV 102 and the current state of charge of the battery 106 of the EV 102. The method 800 may proceed to block 808, wherein the method 800 may include presenting a charging station map user interface that pin points the current geo-location of the EV 102 and the at least one charging station 112.

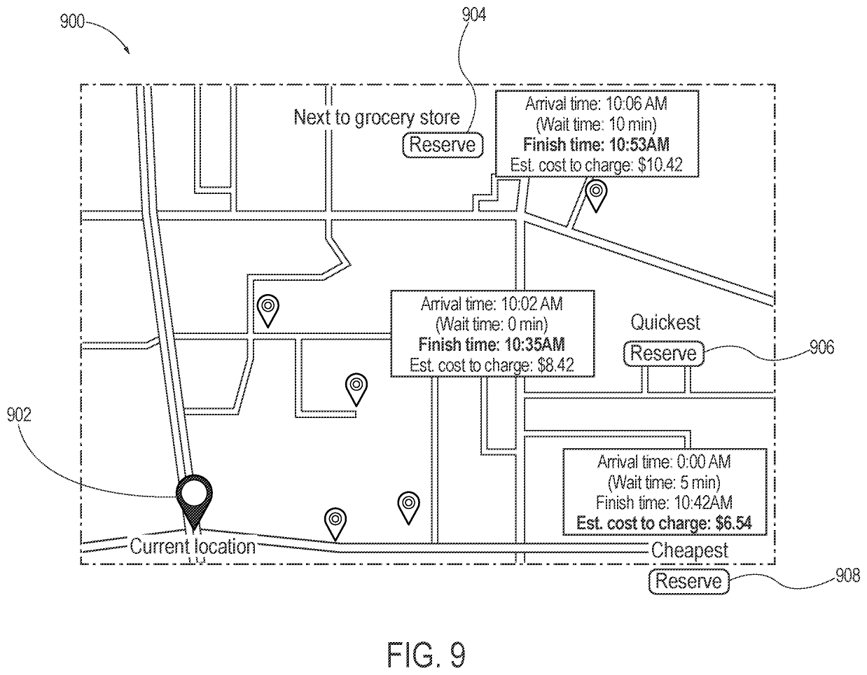

FIG. 9 is an illustrative example of a charging station map user interface 900 for use with a user interface according to an exemplary embodiment of the present disclosure. The charging station map user interface 900 is a charging station map user interface as described above. The charging station map user interface 900 may include user interface selectable geo-locations. Presenting a charging station map user interface that pin points the current geo-location of the electric vehicle and each of the charging stations of the plurality of charging stations may include applying reservation selection inputs, related charging information, and/or a label. The reservation selection inputs allow a user to select an icon to reserve a time or position in a queue associated with a charging station. The related information includes information about the charging stations, electric vehicles, environment, etc. A label identifies a characteristic of a charging station, such as an amenity, feature, or location.

Labels define categories of amenities. A label being applied to a charging station indicates that that the charging station has satisfied the conditions of that label. For example, the category of the label may be based on the dynamic pricing scheme. Suppose that the label is “Cheaper” such that the condition of the label is to only include those charging stations with a charge per kilowatt hour below a threshold value. Charging stations that satisfy the threshold value are annotated with the label “Cheaper.” Furthermore, the labels may be tiered. For example, as an addition or alternative, the category based on the dynamic pricing scheme may include a label “Cheapest.” The “Cheapest” label may be applied to the charging station having the lowest pricing per kilowatt hour. In this manner, a single category may include multiple labels.

As another example of a category, the categories may include charging stations that are capable of fast charging or provide electricity sourced from clean renewable energy sources. For example, charging stations may be labeled as “renewable” if the charging station sources energy from a renewable energy source. In some embodiments, a label may be indicative of certain benefits such as lower pricing or faster charging can be provided during high renewable energy times. Therefore, in addition to the interface allowing the EV operator to visually compare charging rates, charging infrastructure, charging queues, and/or additional charging related information that may pertain to various charging stations 112 relative to the current geo-location 902 of the EV operator or the EV 102. The smart charge application 118 may annotate various charging stations 112 with labels that identify features of the various charging stations 112 that exist in the category. The reservation selection inputs may allow the EV operator reserve a time and/or position in the queue for a charging station 112 by selecting the reservation selection input.

For example, a charging station 112 may be associated with a first reservation selection input 904 that identifies a particular amenity or category of amenity. The amenity or category of amenity may include a label such as “Next to Grocery Store.” A second reservation selection input 906 may have a label that identifies a charging station 112 as the “Quickest” in the map area of the charging station map user interface 900. The determination that a charging selection is the quickest may be based on the charging queue or the charging speed. For example, the quickest may be determined based on real time information from EVs currently charging at the charging station to determine when a currently charging EV will finish. A third reservation selection input 908 may be associated with a label that identifies a charging station 112 as the “Cheapest.” The determination that a charging selection is the cheapest may be based on a dynamic pricing scheme, load on the grid, source of electricity, etc. Accordingly, the reservation selection inputs may include labels that identify different incentives, amenities, and/or categories of amenities associated with the different charging stations. In this manner, a users' charging behavior may be shifted when the load on grid is expected to be high, by increasing the charging price during those times. Thus, the labels can facilitate managing the load on the grid.

The labels may be determined based on related charging information may be based on the current location 902 of the EV 102 as well as other vehicle information including, for example, the speed, direction, planned path of the EV 102, etc. The labels may further be based on related charging information specific to the charging stations, such as the location of the charging station, relative distances between the charging station and other points of interest (e.g., coffee shops, gas stations, grocery stores, parks, attractions, etc.) The labels may be calculated based on one or more aspects of the related charging information and presented as a superlative.

Whether the charging data is based on the EV 102, vehicle information, charging data, and/or the charging station, the data may be collected in real-time via an operable connection for computer communication with the EV 102 and/or the remote server 108, for example, to transmit and receive data, as discussed above. In another embodiment, perspective and/or real-time price data may include charging rates during a certain period of time (e.g., hourly, daily, weekly), charging rates to charge the EV 102 at various charging speeds (e.g., conventional electric vehicle charging speed, fast electric vehicle charging speed, charging power levels) from one or more charging stations.

The EV operator may select a number of categories to be illustrated on the charging station map user interface 900 based on the EV operator's preferences. For example, the EV operator may always want the “Quickest” and “Cheapest” shown but not “Next to Grocery Store.” The EV operator may additionally or alternatively select other categories, such as an Available Public Bathrooms category, a Near Coffee category, near a particular coffee chain category, etc. The EV operator may also apply aggregate user ratings to a category. For example, Available Public Bathrooms with a user rating at or above 4 stars. Therefore, other EV operators may influence the categories and the resulting labels by, for example, rating amenities, leaving comments, categorizing amenities, etc.

Furthermore, the categories may be user defined. For example, distance based categories may have threshold distances selected by the user. The term “next to” may be EV operator defined as with a half mile of the charging station 112 while “near” may be EV operator defined as within two miles of the charging station 112. In this manner, more than one charging station 112 may have a reservation selection input. For example, if the user selects to have “Next to Grocery Store” displayed on the charging station map user interface 900, any charging station 112 within a half mile of a grocery store may be illustrated with a “Next to Grocery Store” reservation selection input. In another embodiment, the term “next to” may indicate the charging station 112 that is geographically or path-based closest to an amenity. For example, only the charging station 112 closest to a grocery store may be illustrated with a “Next to Grocery Store” reservation selection input.

In addition to displaying the reservation selection inputs for selected categories, the smart charge application 118 may display selected charging information such as the arrival time, wait time, finish time, estimated cost to charge, etc. so that the EV operator can quickly assess the information that reservation selection inputs are based on. For example, suppose that the second reservation selection input 906 identifies a charging station 112 as the “Quickest” with a Quickest Label having no wait time, but the third reservation selection input 908 identifies another charging station 112 as the “Cheapest” with a Cheapest Label having only a five minute wait time. The EV operator may prefer the third reservation selection input 908 because it is the cheapest if the associated charging station 112 only has a five minute wait. Alternatively, the EV operator may prefer the second reservation selection input 906 because it is the quickest if the associated charging station 112 is only $1.88 more expensive. In this manner, a reservation selection input may be illustrated for charging station 112 with related charging information.

The arrival time of the EV 102 for the related charging information may be based on the current location 902 of the EV 102 as well as other vehicle information including, for example, the speed, direction, planned path of the EV 102, etc. The wait time may be based on the current queue at the charging station 112 or the expected queue at the charging station 112 at the arrival time. The finish time may be based on real-time data, such as the SOC of the EV 102, the expected SOC of the EV 102 at the arrival time, the charging speed of the charging station 112, the EV operator preferences, the wait caused by any vehicle currently charging at the charging station, etc. For example, determining the finish time may include receiving real-time data from at least one charging station within the remaining distance or within the remaining distance within a predetermined distance of the at least one perspective travel path of the electric vehicle. Accordingly, information about currently charging electric vehicles at the charging stations may be used to determine the finish time of the EV 102. Likewise, the estimated cost to charge the EV 102 may also be based on the SOC of the EV 102, the expected SOC of the EV 102 at the arrival time, the charging speed of the charging station 112, the EV operator preferences, etc. Accordingly, EV operators may reserve the at least one charging station for charging the electric vehicle by selecting one or more labels based on incentives, amenities, categories of amenities.

In some embodiments, the charging information may be visually emphasized based on the label associated with the reservation selection inputs. For example, if the second reservation selection input 906 is labeled “Quickest” then the related charging information for Finish Time may be emphasized whereas if the third reservation selection input 908 is labeled “Cheapest” then the Estimated Cost to Charge may be emphasized. The emphasis on the charging station map user interface 900 may be illustrated with fonts that are bold, underlined, italicized, in color, and/or highlighted, among others.

It should be apparent from the foregoing description that various exemplary embodiments of the disclosure may be implemented in hardware. Furthermore, various exemplary embodiments may be implemented as instructions stored on a non-transitory machine-readable storage medium, such as a volatile or non-volatile memory, which may be read and executed by at least one processor to perform the operations described in detail herein.

A machine-readable storage medium may include any mechanism for storing information in a form readable by a machine, such as a personal or laptop computer, a server, or other computing device. Thus, a non-transitory machine-readable storage medium excludes transitory signals but may include both volatile and non-volatile memories, including but not limited to read-only memory (ROM), random-access memory (RAM), magnetic disk storage media, optical storage media, flash-memory devices, and similar storage media.

It should be appreciated by those skilled in the art that any block diagrams herein represent conceptual views of illustrative circuitry embodying the principles of the disclosure. Similarly, it will be appreciated that any flow charts, flow diagrams, state transition diagrams, pseudo code, and the like represent various processes which may be substantially represented in machine readable media and so executed by a computer or processor, whether or not such computer or processor is explicitly shown.

It will be appreciated that various implementations of the above-disclosed and other features and functions, or alternatives or varieties thereof, may be desirably combined into many other different systems or applications. Also that various presently unforeseen or unanticipated alternatives, modifications, variations or improvements therein may be subsequently made by those skilled in the art which are also intended to be encompassed by the following claims.

1. A computer-implemented method for presenting electric vehicle charging options, comprising:
determining a current geo-location of an electric vehicle;
determining a current state of charge of a battery of the electric vehicle;
identifying a plurality charging stations that are within a remaining distance that the electric vehicle is capable of traveling based on the current geo-location of the electric vehicle and the current state of charge of the battery of the electric vehicle;
presenting a charging station map user interface that pin points the current geo-location of the electric vehicle and each of the charging stations of the plurality of charging stations, wherein one or more of the charging stations are presented with labels; and
reserving a charging station of the plurality of charging stations by selecting a label of the one or more charging stations that is presented on the charging station map user interface.

2. The computer-implemented method of claim 1, wherein determining the current state of charge further includes determining the remaining distance that the electric vehicle is capable of traveling based on analyzing the current state of charge of the electric vehicle, an average speed of the electric vehicle, and at least one road type that is located within a vicinity of the current geo-location of the electric vehicle.

3. The computer-implemented method of claim 1, wherein the label is presented with charging stations based on a category that satisfy conditions associated of the label.

4. The computer-implemented method of claim 3, wherein the category is based on a dynamic pricing scheme, and the label includes a Cheapest label.

5. The computer-implemented method of claim 3, wherein the category is based on a finish time, and includes a Quickest label.

6. The computer-implemented method of claim 5, wherein determining the finish time includes receiving real-time data from at least one charging station that is within the remaining distance that the electric vehicle is capable of traveling.

7. The computer-implemented method of claim 6, wherein the real-time data includes charging data for a currently charging electrical vehicle.

8. A system for presenting electric vehicle charging options, comprising:
a memory storing instructions when executed by a processor cause the processor to:
determine a current geo-location of an electric vehicle;
determine a current state of charge of a battery of the electric vehicle;
determine a plurality of charging stations that are within a remaining distance that the electric vehicle is capable of traveling based on the current geo-location of the electric vehicle and the current state of charge of the battery of the electric vehicle;
present a charging station map user interface that pin points the current geo-location of the electric vehicle and at least one charging station of the plurality of charging station, wherein one or more of the charging stations are presented with labels; and
reserve a charging station of the plurality of charging stations by selecting a label of the one or more charging stations that is presented on the charging station map user interface.

9. The system of claim 8, wherein determining the current state of charge further includes determining the remaining distance that the electric vehicle is capable of traveling based on analyzing the current state of charge of the electric vehicle, an average speed of the electric vehicle, and at least one road type that is located within a vicinity of the current geo-location of the electric vehicle.

10. The system of claim 8, wherein the label is presented with charging stations based on a category that satisfy conditions associated of the label.

11. The system of claim 10, wherein the category is based on a dynamic pricing scheme, and the label includes a Cheapest label.

12. The system of claim 10, wherein the category is based on a finish time, and includes a Quickest label.

13. The system of claim 12, wherein determining the finish time includes receiving real-time data from at least one charging station that is within the remaining distance that the electric vehicle is capable of traveling.

14. The system of claim 13, wherein the real-time data includes charging data for a currently charging electrical vehicle.

15. A non-transitory computer readable storage medium storing instructions that when executed by a computer, which includes a processor perform a method, the method comprising:
determining a current geo-location of an electric vehicle;
determining a current state of charge of a battery of the electric vehicle;
identifying a plurality charging stations that are within a remaining distance that the electric vehicle is capable of traveling based on the current geo-location of the electric vehicle and the current state of charge of the battery of the electric vehicle;
presenting a charging station map user interface that pin points the current geo-location of the electric vehicle and each of the charging stations, wherein one or more of the charging stations are presented with labels; and
reserving a charging station of the plurality of charging stations by selecting a label of the one or more charging stations that is presented on the charging station map user interface.

16. The non-transitory computer readable storage medium of claim 15, wherein determining the current state of charge further includes determining the remaining distance that the electric vehicle is capable of traveling based on analyzing the current state of charge of the electric vehicle, an average speed of the electric vehicle, and at least one road type that is located within a vicinity of the current geo-location of the electric vehicle.

17. The non-transitory computer readable storage medium of claim 15, wherein the label is presented with charging stations based on a category that satisfy conditions associated of the label.

18. The non-transitory computer readable storage medium of claim 17, wherein the category is based on a dynamic pricing scheme, and the label includes a Cheapest label.

19. The non-transitory computer readable storage medium of claim 17, wherein the category is based on a finish time, and includes a Quickest label.

20. The non-transitory computer readable storage medium of claim 19, wherein determining the finish time includes receiving real-time data from at least one charging station that is within the remaining distance.
